(19) United States
(12) Patent Application Publication
(10) Pub. No.: US 2016/0008713 A1
(43) Pub. Date: Jan. 14, 2016

(54) KEY APPARATUS

(71) Applicant: HON HAI PRECISION INDUSTRY CO., LTD., New Taipei (TW)

(72) Inventors: CHIA-SHOU CHANG, New Taipei (TW); HSIEN-JEN CHEN, New Taipei (TW); CHAO-TE LEE, New Taipei (TW)

(21) Appl. No.: 14/546,866

(22) Filed: Nov. 18, 2014

(30) Foreign Application Priority Data
Jul. 10, 2014 (TW) 103123820

(51) Int. Cl. A63F 13/24; H05K 5/02; H05K 5/00

(52) U.S. Cl. CPC A63F 13/24; H05K 5/0026; H05K 5/02

(57) ABSTRACT

A key apparatus includes a housing with an opening, a printed circuit board (PCB) received in the housing, and a key mechanism. The key mechanism includes at least one key and an elastic portion. The key and the elastic portion are partly exposed from the housing via the opening. The elastic portion deforms to generate an elastic force and the key remains in an original position. The elastic drives the key to move simultaneously for providing an elastic force. The key mechanism provides a two stage touch feeling to a user when being pressed.

### CROSS-REFERENCE TO RELATED APPLICATIONS

This application claims priority to Taiwan Patent Application No. 103123820 filed on Jul. 10, 2014, the contents of which are incorporated by reference herein.

### FIELD

The present disclosure relates to key apparatus for improving touch sensitivity.

### BACKGROUND

A key apparatus, such as a game controller, includes at least one pressed key, at least one rubber portion with conductive particles, and at least one pressing film. The pressing film defines different connected area ranges corresponding to different control signals respectively. When a key is pressed, the corresponding conductive particle connects with the pressing film for generating different control signals based on different connected area.

### BRIEF DESCRIPTION OF THE FIGURES

Implementations of the present technology will now be described, by way of example only, with reference to the attached figures.

FIG. 1 is an isometric view of an embodiment of a key apparatus, the key apparatus comprising a rubber portion.

FIG. 2 is an exploded view of an embodiment of the key apparatus of FIG. 1.

FIG. 3 is an isometric view of an embodiment of the rubber portion of FIG. 1 viewed from another angle.

FIG. 4 is a cross-section view of an embodiment of the key apparatus of FIG. 1, taken along a line IV-IV thereof.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

The term “substantially” is defined to be essentially conforming to the particular dimension, shape or other word that substantially modifies, such that the component need not be exact. For example, substantially cylindrical means that the object resembles a cylinder, but can have one or more deviations from a true cylinder. The term “comprising” means “including, but not necessarily limited to”; it specifically indicates open-ended inclusion or membership in a so-described combination, group, series and the like.

A key apparatus capable of improving touch sensitivity is described.

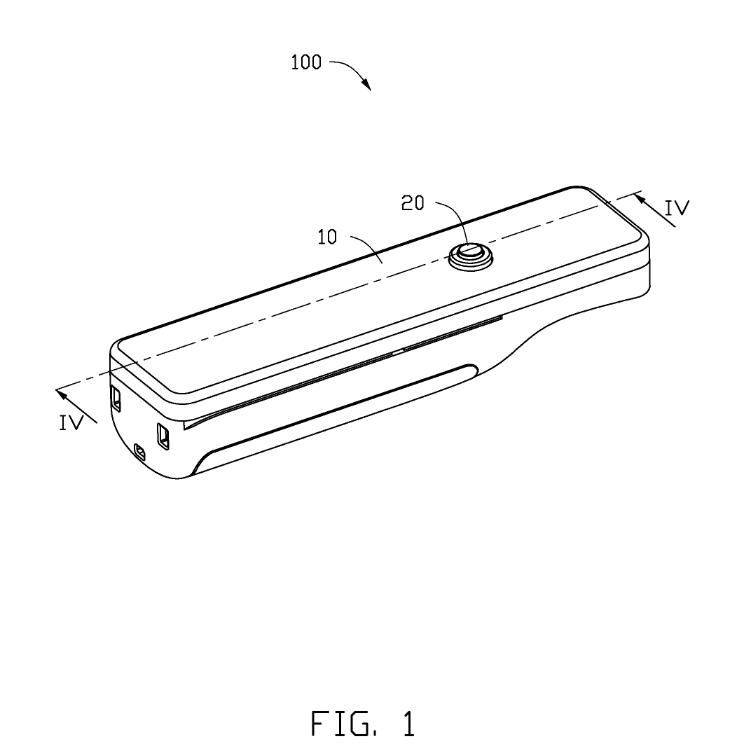

FIG. 1 illustrates a key apparatus 100 of the embodiment. The key apparatus 100 generates different control signals for controlling an external device to execute a corresponding function based on difference pressures. In the embodiment, the key apparatus 100 is a game controller.

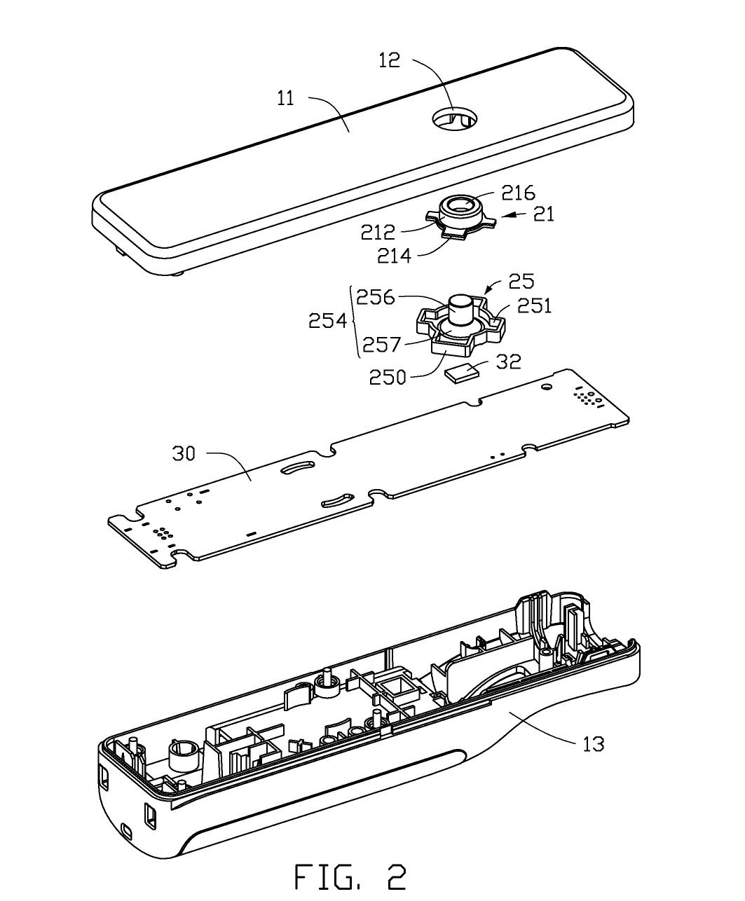

FIG. 2 illustrates the key apparatus 100 includes a housing 10, a key mechanism 20, and a printed circuit bard (PCB) 30. The key mechanism 20 and the PCB 30 are received in the housing 10. Parts of the key mechanism 20 are exposed from the housing 10.

The housing 10 includes an upper cover 11 and a bottom cover 13 cooperated with the upper cover 11 to define a receiving space (not shown). The upper cover 11 defines an opening 12. In other embodiments, the upper cover 11 can defines at least two openings 12.

The key mechanism 20 is located on the PCB 30. The key mechanism 20 includes a key 21 and an elastic portion 25. The key 21 includes a first body 212, a plurality of protruding portions 214, and a through hole 216. The first body 212 is substantially cylinder shaped. A diameter of first body 212 is less than a diameter of the opening 12. The protruding portions 214 adjacent to the bottom surface of the first body 212 are symmetrically protruded from the sidewall of the first body 212 along a direction perpendicular to an axis of the first body 212. The protruding portion 214 is substantially rectangular plate. The through hole 216 is concaved from an upper surface of the first body 212 to the bottom surface of the first body 212. An axis of the through hole 216 is overlapped with the axis of the first body 212. In at least one embodiment, there are four protruding portions 214. The key 21 is made of elastic material. In other embodiments, the key mechanism 20 includes at least two keys 21 and at least two elastic portions 25 corresponding to the keys 21 in an one-to-one relationship.

The elastic portion 25 is substantially cross-shaped. The elastic portion 25 includes a second body 250, a receiving portion 251, a trigging portion 254, and a slot 258. The second body 250 is substantially cross-shaped. A diameter of the second body 250 is less than a diameter of the through hole 216.

The receiving portion 251 is concaved from a surface opposite to the second body 250. The receiving portion 251 is used for receiving the protruding portion 214.

The trigging portion 254 is located on a central of the receiving portion 251. The trigging portion 254 includes a protruding pole 256 and a connecting portion 257. The protruding pole 256 is substantially cylinder shaped. The protruding pole 256 is protruded from a central of the receiving portion 251 along a direction adjacent to the key 21. An end of the protruding pole 256 passes through the through hole 216 and the opening 12 to be exposed from the housing 10. The protruding pole 256 and the key 21 define an altitude difference. A distance between the protruding pole 256 and the upper cover 11 is greater than a distance between the key 21 and the upper cover 11. An opposite end of the protruding pole 256 passes through the receiving portion 251 and is received in the slot 258. The connecting portion 257 connects the protruding pole 256 and the receiving portion 251. The connecting portion 257 and a bottom surface of the receiving portion 251 define an angle. The connecting portion 257 is a substantially hollow frustum of a cone. An upper edge of the connecting portion 257 is connected to the protruding pole 256, and a lower edge of the connecting portion 257 is connected to a bottom surface of the receiving portion 251. In at least one embodiment, the connecting portion 257 is made of elastic material.

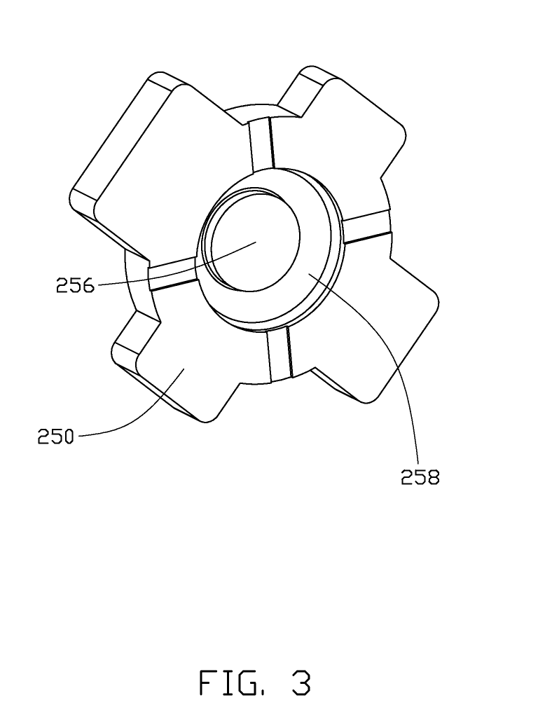

FIG. 3 illustrates that the slot 258 is concaved from a surface of the second body 250 along a direction away from the PCB 30. The slot 258 is substantially a frustum of a cone. The slot 258 receives an end of the protruding pole 256.

The PCB 30 is substantially a rectangular plate. The PCB 30 includes a sensing portion 32. The sensing portion 32 mounted on the PCB 30 corresponds to the slot 258. The sensing portion 32 generates different control signals based on different pressures. An area of the sensing portion 32 is similar to an area of a cross section of the protruding pole 256. In at least embodiment, the sensing portion 32 is a pressure sensor.

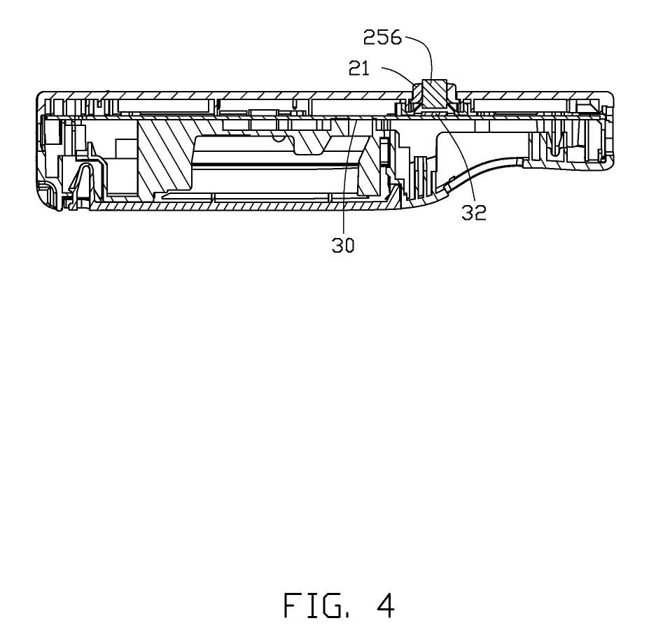

FIG. 4 illustrates the key apparatus 100 in assembly. The second body 250 is located on the PCB 30. The sensing portion 32 is received in the slot 258, and spaces from the protruding pole 256 in a predetermined distance. The predetermined distance is equal to the altitude difference. The first body 212 sleeves on the protruding pole 256 and connects with the connecting portion 257. Partial of the first body 212 and the protruding pole 256 are exposed from the housing 10 via the opening 12.

While a force is pressed on the protruding pole 256, the protruding pole 256 drives the trigging portion 254 and the connecting portion 257 to move down for resisting with the PCB 30 simultaneously, which causes a bottom surface of the slot 258 connects with a region of the PCB 30 around the sensing portion 32. Meanwhile, the elastic portion 25 deforms to generate an elastic force along a direction away from the PCB 30 for improving a touch feeling of the key mechanism 100. The connecting portion 257 supports the key 21 to maintain in an original position. Then the key 21 and the protruding pole 256 simultaneously quickly move down to connect the PCB 30 in a short while. The end of the protruding pole 256 received in the slot 258 connects with the sensing portion 32, and is deformed for improving a touch feeling of the key apparatus 100. When the protruding pole 256 resists with the sensing portion 32, the protruding portion 214 is completely received in the receiving portion 251, and the sensing portion 32 generates a corresponding control signal based on the force supplied to the key 21. When the force pressed on the key 21 is released, the deformed elastic portion 25 and the deformed key 21 resume to an original position based on the generated elastic force.

In use, the key apparatus 100 provides two stage touch feelings while pressing the key mechanism 100, and a sensitivity of the key apparatus 100 is improved by the pressure type sensing portion 32.

While various exemplary and preferred embodiments have been described, the disclosure is not limited thereto. On the contrary, various modifications and similar arrangements (as would be apparent to those skilled in the art) are intended to also be covered. Therefore, the scope of the appended claims should be accorded the broadest interpretation so as to encompass all such modifications and similar arrangements.

What is claimed is:

1. A key apparatus comprising:
a housing with an opening;
a printed circuit board (PCB) received in the housing and comprising a sensing portion; and
a key mechanism located on the PCB,
wherein the key mechanism comprises an elastic portion and at least one key sleeved on the elastic portion;
the key and the elastic portion are partly exposed from the housing via the opening;
and the key and the elastic portion define an altitude difference.

2. The key apparatus of claim 1, wherein the key comprises a first body; the elastic portion comprises a second body, a receiving portion, and a trigging portion located at a central of the receiving portion; the first body defines a through hole; the first body sleeves on the trigging portion via the through hole.

3. The key apparatus of claim 2, wherein an axis of the through hole is overlapped with an axis of the first body.

4. The key apparatus of claim 2, wherein the elastic portion further comprises a slot; the slot and the receiving portion are respectively concaved from opposite surface of the second body; the slot receives the sensing portion.

5. The key apparatus of claim 4, wherein the trigging portion comprises a protruding pole for pressing the sensing portion; the protruding pole is located at the central of the receiving portion; an end of the protruding pole is passed through the first body and the opening simultaneously to be exposed from the housing; an opposite end of the protruding pole passes through the receiving portion to be received in the slot.

6. The key apparatus of claim 5, wherein the trigging portion further comprises a connecting portion; the connecting portion connects between the protruding pole and the receiving portion; the connecting portion and a bottom surface of the receiving portion define an angle.

7. The key apparatus of claim 5, wherein the protruding pole is spaced from the sensing portion in a predetermined distance; the altitude difference is equal to the predetermined distance.

8. The key apparatus of claim 6, wherein the key further comprises a plurality of protruding portions; the protruding portion is resisted with the connecting portion and apart from the receiving portion; when the elastic portion moves, the protruding portion presses the connecting portion to be deformed.

9. The key apparatus of claim 8, wherein when the key and the elastic portion simultaneously move, the protruding portion is completely received in the receiving portion.

10. The key apparatus of claim 8, wherein the protruding portions are symmetrically located on sidewall of the first body along an axis of the first body.

11. An key apparatus, comprising:
a housing with an opening;
a printed circuit board (PCB) received in the housing, comprising a sensing portion; and
a key mechanism located on the PCB;
wherein the key mechanism comprises an elastic portion and a key sleeved on the elastic portion; the key and the elastic portion are partly exposed from the housing via the opening; the elastic portion deforms to generated an elastic force by an external force and the key remains in an original position; the elastic portion drives the key to move simultaneously for providing an elastic force; the elastic force generated by the elastic portion and the key resumes the elastic portion and the key to the original position when the external force is released.

12. The key apparatus of claim 11, wherein the key and the elastic portion define an altitude difference.

13. The key apparatus of claim 11, wherein the key comprises a first body; the elastic portion comprises a second body, a receiving portion, and a trigging portion located at a central of the receiving portion; the first body defines a through hole;
the first body sleeves on the trigging portion via the through hole.

14. The key apparatus of claim 13, wherein an axis of the through hole is overlapped with an axis of the first body.

15. The key apparatus of claim 13, wherein the elastic portion further comprises a slot; the slot and the receiving portion are respectively concaved from opposite surface of the second body; the slot receives the sensing portion.

16. The key apparatus of claim 13, wherein the trigging portion comprises a protruding pole for pressing the sensing portion; the protruding pole is located at the central of the receiving portion; an end of the protruding pole is passed through the first body and the opening simultaneously to be exposed from the housing; an opposite end of the protruding pole passes through the receiving portion to be received in the slot.

17. The key apparatus of claim 13, wherein the trigging portion further comprises a connecting portion; the connecting portion connects between the protruding pole and the receiving portion; the connecting portion and a bottom surface of the receiving portion define an angle.

18. The key apparatus of claim 16, wherein the protruding pole is spaced from the sensing portion in a predetermined distance; the altitude difference is equal to the predetermined distance.

19. The key apparatus of claim 17, wherein the key further comprises a plurality of protruding portions; the protruding portion is resisted with the connecting portion and apart from the receiving portion; when the elastic portion moves, the protruding portion presses the connecting portion to be deformed.

20. The key apparatus of claim 19, wherein the protruding portions are symmetrically located on sidewall of the first body along an axis of the first body.
